(19) United States
(12) Patent Application Publication
(10) Pub. No.: US 2004/0206960 A1
(43) Pub. Date: Oct. 21, 2004

(54) Light emitting element and light emitting display

(76) Inventor: Ryuji Nishikawa, Gifu-shi (JP)

Correspondence Address: CANTOR COLBURN, LLP, 55 GRIFFIN ROAD SOUTH, BLOOMFIELD, CT, 06002

(21) Appl. No.: 10/807,656

(22) Filed: Mar. 24, 2004

(30) Foreign Application Priority Data
Mar. 28, 2003 (JP) 2003-92535

(51) Int. Cl. H01L 29/04

(52) U.S. Cl. 257/72

(57) ABSTRACT

A light emitting element such as an organic EL element comprises a first electrode formed of a transparent electrode on a side from which light is emitted to outside, and a second electrode formed on a back side of the element so as to be opposed to the first electrode with a light emitting element layer interposed therebetween. The second electrode is designed to be a semitransparent electrode, and, on a further back side of the second electrode, an antireflective layer with a low optical reflectivity is formed. The semitransparent second electrode does not reflect but transmits light incident from outside of the element and transmitted through the transparent electrode, and then the antireflective layer absorbs the transmitted light, thereby making it possible to suppress reflection of ambient light on a surface of the back-side electrode and to achieve improvement in contrast. The second electrode may, for example, be made of a metal material formed as a thin film, or be provided with apertures to thereby exhibit semitransparency.

### BACKGROUND OF THE INVENTION

1. Field of the Invention

The present invention relates to a structure of a light emitting element as used in a display or the like, and in particular to a structure on the back side of a light emitting element.

2. Description of the Related Art

Recently, a great deal of attention has come to be focused on electroluminescence (hereinafter, referred to as EL) elements as light emitting elements, and research is being conducted on displays which use such EL elements. This research is directed at, for example, creating substitutes for displays such as liquid crystal displays (LCDS) or CRTs.

Among various types of EL element, an organic EL element which uses an organic compound as a light emitting material has a structure wherein a light emitting element layer containing organic light emitting molecules is interposed between a hole injection electrode (anode) and an electron injection electrode (cathode). More specifically, a transparent electrically conductive layer made of ITO (Indium Tin Oxide) is formed as the hole injection electrode on a transparent glass substrate, the light emitting element layer having a single-layer or multilayer structure is layered on the hole injection electrode, and an opaque metal electrode made of Al, Ag, MgAg, or the like is formed as the electron injection electrode on the light emitting element layer.

In such a structure, holes injected from the hole injection electrode and electrons injected from the electron injection electrode are recombined in the light emitting element layer to excite the organic light emitting molecule contained in this layer. Light emitted when the excited molecule returns to a ground state, is transmitted through the transparent hole injection electrode and glass substrate, and is then emitted to the outside.

With this structure, because a highly reflective metal material is commonly used for the metal electrode located on a back side opposite to a light emitting side (viewing side), ambient light which enters the element through the substrate and the transparent electrode is reflected at an interface on the light emitting element layer side. The reflection of ambient light becomes a major cause of contrast reduction especially when the display displays black, and, in addition, because a surrounding image may be projected onto the viewing surface (reflective surface) of the metal electrode, reduction in visibility of a displayed image may occur, thus causing reduction in display quality.

As a simple and easy method for preventing such reduction in display quality due to the reflection on the metal electrode, a polarization layer as used in an LCD may be disposed on the transparent glass substrate or on the glass substrate side of the transparent hole injection electrode, that is, on the viewing surface (light emitting surface) side of the element, which is disclosed in, for example, Japanese Patent Laid-Open Publication No. Hei 7-142170.

As described in the above-noted Japanese Patent Laid-Open Publication No. Hei 7-142170, a polarization layer is disposed on the light emitting surface side of the element so that the polarization layer can block light that would normally enter the element from outside the element, be reflected by the metal electrode on the back side, and then emitted back from the element. In practical applications, the polarization layer comprises a λ/4 phase plate placed closer to the element than a polarization film.

More specifically, light that enters from outside the element through the polarization layer is linearly polarized light which is parallel to the polarization direction of the polarization layer. When this linearly polarized light is reflected by the metal electrode and reaches the polarization layer again, because the light passes through the λ/4 phase plate twice in a round trip, the polarization direction is rotated by 90°. Thus, the polarization direction of the light that has been reflected by the metal electrode and passed through the phase plate differs from that of the polarization layer by 90°, and therefore the reflected light cannot pass through the polarization layer, and is blocked.

The phase plate and the polarization layer thus provided can prevent emission of light reflected from the light emitting surface, and prevent reduction in contrast. However, because the polarization layer is on the light emitting side of the structure, light emitted from the light emitting layer must pass through the polarization layer in order to be emitted to outside and, because the polarization plate only transmits light which is emitted from the light emitting layer and has a polarization direction parallel to the polarization direction of the polarization layer, a large portion of the emitted light is absorbed and cannot pass through the polarization layer. Thus, the efficiency of use of the emitted light is significantly reduced due to the existence of the polarization layer. To increase the amount of light actually emitted from the element, the emission luminance of the organic EL element must be increased. For this purpose, it is necessary to increase the amount of current to be fed through between the hole injection electrode and the electron injection electrode (through the light emitting element layer).

However, there is a problem in that, in an organic EL element, when the amount of current fed through a light emitting element layer containing an organic compound such as a light emitting molecule is increased, luminance is more rapidly reduced, and the life span of the element is shortened. On the other hand, in order to achieve a high luminance without increasing the amount of current, development of a novel organic light emitting material capable of high-efficiency light emission is required, and, in order that the element have a long life span even under heavier current loads, development of a novel organic light emitting material with high durability is required.

### SUMMARY OF THE INVENTION

In consideration of the above-described problems, the present invention provides a light emitting element and a light emitting display that enables high contrast, a long life span, and a high brightness.

According to one aspect of the present invention, there is provided a light emitting element comprising a light emitting element layer between a first electrode and a second electrode, wherein one of the first electrode and the second electrode is disposed as a light-emitting-side electrode, which is formed on a side from which light is emitted to outside, another one of the first electrode and the second electrode as a back-side electrode positioned on a back side of the light-emitting-side electrode is formed as a semitransparent electrode for partially transmitting incident light from a side of the light emitting element layer, and an antireflective layer is provided on a back side of the semitransparent electrode.

According to another aspect of the present invention, there is provided a light emitting display comprising a light emitting element with a light emitting element layer provided between a first electrode and a second electrode, wherein the first electrode is formed over a transparent substrate disposed on a side from which light is emitted to outside of the display and is an electrode capable of transmitting light emitted from the light emitting element layer, the second electrode is formed on a back side of the first electrode so as to be opposed to the first electrode with the light emitting element layer interposed therebetween and is a semitransparent electrode for partially transmitting incident light from a side of the light emitting element layer, and an antireflective layer is provided on a back side of the second electrode.

According to still another aspect of the present invention, there is provided a display comprising an electroluminescence element with a light emitting element layer provided between an anode and a cathode, wherein the anode is formed over a transparent substrate disposed on a side from which light is emitted to outside and comprises an electrode capable of transmitting light emitted from the light emitting element layer, the cathode is formed on a back side of the anode so as to be opposed to the anode with the light emitting element layer interposed therebetween and comprises a semitransparent electrode capable of partially transmitting incident light from a side of the light emitting element layer, and an antireflective layer is formed on a back side of the cathode.

As described above, in the light emitting element, a semitransparent electrode is used as the back-side electrode positioned on the back side relative to the light-emitting-side electrode, and a low-reflectivity layer or an antireflective layer is provided on a further back side of the back-side electrode, thereby preventing ambient light incident into the element from being reflected on a surface of the back-side electrode, and allowing the light to be transmitted through the back-side electrode and absorbed by the antireflective layer with a low reflectivity. Light that travels from the light emitting element layer to the transparent light-emitting-side electrode can pass through the light-emitting-side electrode and then pass through the transparent substrate. Thus, this light can be emitted to the outside of the element efficiently and with minimum loss. Therefore, although light emitted from the light emitting element layer and traveling to the back-side electrode side is not reflected but absorbed by the antireflective layer, as is the case with ambient light, reduction in contrast due to reflection of ambient light can be avoided so that improvements in display quality because of the improvement in contrast can be achieved, such as a light emitting element that is easily visible and has a visually distinguishable high effective brightness, which are advantageous even though the light traveling to the back-side electrode side is lost.

According to still another aspect of the present invention, it is preferable that, in the light emitting element or the display, a metal layer with a thickness reduced to a level of a thin film through which light can be transmitted or a metal layer with a mesh pattern provided with apertures for transmitting light is used in the semitransparent electrode.

According to still another aspect of the present invention, it is preferable that, in the light emitting element or the display, an Ag layer or an MgAg layer with a thickness of 20 nm or less is used in the semitransparent electrode.

As described above, the metal layer may be formed to have a reduced thickness or apertures so that light can be transmitted without changing the material of the electrode as such, and such a metal layer can be adopted to exercise the necessary functions as an electrode.

According to still another aspect of the present invention, it is preferable that, in the light emitting element or the display, molybdenum or a chromium oxide is used in the low-reflectivity layer or the antireflective layer.

By employing either molybdenum or a chromium oxide for the antireflective layer, it is possible to easily form a layer with a low optical reflectivity on the surface on a further back side of the back-side electrode to prevent ambient light transmitted through the semitransparent back-side electrode from being reflected and emitted back from the element.

According to still another aspect of the present invention, it is preferable that, in the display further comprising a plurality of pixels, each pixel comprises a light emitting element as described above and a thin-film transistor for controlling light emission from the light emitting element, the thin-film transistor is formed closer to the substrate than the light emitting element, and an antireflective light-blocking layer for blocking entry of ambient light and for preventing reflection of ambient light is provided between at least a region where an active layer of the thin-film transistor is formed and the substrate.

By providing such an antireflective light-blocking layer between the substrate and the light emitting element or the electroluminescence element, it is possible to avoid a leakage current which often occurs due to ambient light incident on the thin-film transistor and which consequently causes a deviation of the emission brightness from the content to be displayed. In addition, because reflection of ambient light coming from the viewing side by the surface can be avoided, the antireflective light-blocking layer can also contribute to improved display contrast.

As described above, according to the present invention, reflection of ambient light by a back-side electrode can be reduced, and a high-contrast light emitting element and a display using such a light emitting element can be realized.

### BRIEF DESCRIPTION OF THE DRAWINGS

FIG. 1 shows a schematic cross-sectional structure of an organic EL element according to a preferred embodiment of the present invention.

FIG. 2 shows an example of a structure of a semitransparent second electrode in the organic EL element according to a preferred embodiment of the present invention.

FIG. 3 shows a schematic circuit layout of an active-matrix organic EL display according to a preferred embodiment of the present invention.

FIG. 4 shows a partial cross section of one pixel in the display shown in FIG. 3.

### DESCRIPTION OF PREFERRED EMBODIMENT

A preferred embodiment (hereinafter, referred to as an “embodiment”) of the present invention will be described with reference to the drawings.

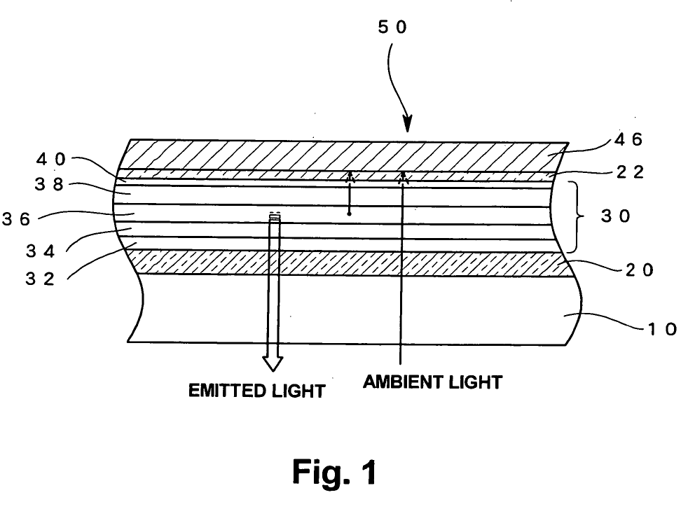

An EL element is suitable as an example light emitting element according to the embodiment of the present invention. Using such an EL element as an illustrative example, FIG. 1 shows a schematic cross section of an element according to this embodiment of the present invention. A transparent substrate made of glass, plastic, or the like is used as a substrate 10, and components of an EL element are layered over the transparent substrate 10. In this example, an EL element 50 is an organic EL element which uses an organic compound as a light emitting material, and a light emitting element layer 30 containing the organic compound is formed between a first electrode 20 and a second electrode 22.

In the organic EL element 50 as shown in FIG. 1, the first electrode 20 is made of a transparent electrically conductive material such as an ITO (Indium Tin Oxide) or an IZO (Indium Zinc Oxide) to form a transparent electrode (an optically transparent electrode; however, a semitransparent electrode with a somewhat low optical transmittance is also applicable) which has a function of injecting holes in this example case. The first electrode 20 is formed directly on the transparent substrate 10 or, otherwise, with a buffer layer, a transistor for driving an organic EL element, or the like formed therebetween. The light emitting element layer 30 formed over the first electrode 20 has a single-layer or multilayer structure containing an organic compound, and the semitransparent second electrode 22 which has a function of injecting electrons is formed over the light emitting element layer 30 so as to be opposed to the first electrode 20. Further, as an upper layer formed above the second electrode 22, or, in other words, on a further back side of the second electrode 22 as viewed from the transparent substrate 10 as the viewing side, an antireflective layer 46 is formed of, for example, a chromium oxide (CrOx: x represents an arbitrary number) layer or a molybdenum (Mo) layer, which has a low reflectivity to incident light.

Although various structures may be adopted for the light emitting element layer 30 as suits factors such as, for example, the function of an organic compound in use, for example, a single-layer structure of an organic light emitting layer having a light emitting function, a hole transport function, and an electron transport function, or a three-layer structure in which a hole transport layer, a light emitting layer, and an electron transport layer are successively layered from the hole injection electrode (anode) 20 side is applicable. The light emitting element layer 30 as shown in FIG. 1 has, on the hole injection electrode 20, a multilayered structure of a hole injection layer 32 containing CFx or the like, a hole transport layer 34 containing a triphenylamine derivative such as NPB or the like, a light emitting layer 36 containing an organic light emitting molecule according to the color of light to be emitted, an electron transport layer 38 containing Alq₃ or the like, and an electron injection layer 40 made of LiF or the like.

In the light emitting layers 36, respective materials appropriate for obtaining light of RGB colors are used.

When the light emitting element layer 30 is formed of a layer containing a low-molecular-weight organic compound, the constituent layers of the light emitting element layer 30 can be formed in respective desired thicknesses by, for example, a vacuum evaporation method. Otherwise, when the light emitting element layer 30 is formed of a layer containing a high-molecular-weight compound, the layer can be formed using an ink jet printing method, a spin coating method, or the like.

In the example case of FIG. 1, the second electrode 22 functions as a cathode in which efficient injection of electrons into the light emitting element layer 30 is required. As a material having a high-level electron injecting function, a metal or metallic material with a small work function is suitable, as such usually have low optical transmittance. For example, the above-listed Al, Ag, MgAg alloy, or the like is applicable. However, if too much importance is placed on the function as an electrode and, for example, an Al layer or an Ag layer formed in a thickness of about 200 nm is used as the electrode, reflection occurs on the surface of the light emitting element layer 30 side. As a result, contrast reduction due to the reflection of ambient light occurs as described above.

When a layer of an appropriate electron injecting material such as Al, Ag, or AgMg is used for the second electrode 22, according to the present embodiment, first, the thickness of the second electrode 22 is reduced to a level of a thin film of, for example, about 5 nm to 40 nm so that a certain level of optical transmittance can be ensured. For example, with Ag formed as a thin film of about 20 nm, an optical transmittance of 50% or higher, in other words, a semitransparent electrode is achieved without impairing the electron injecting function. A metal material such as Al can be formed by, for example, a vacuum evaporation method or the like as in the above-described case of the constituent layers of the light emitting element layer 30, and the thickness can be precisely controlled to form a thin film with a desired thickness through adjustment of the evaporation time or the like.

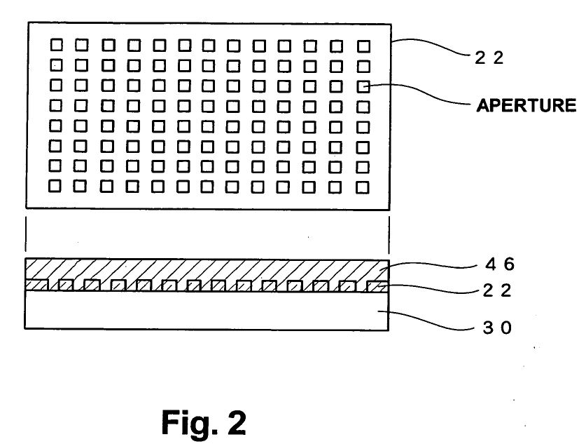

Alternatively, according to another method for achieving semitransparency while using a light-blocking metal material such as Al or the like as a material of the second electrode 22, as shown in FIG. 2, the metal second electrode 22 may comprise apertures arranged in a mesh pattern (including a grid pattern) through which light can be transmitted, with at least one aperture provided in each unit display area such as a pixel. Although the apertures may be of any shape, such as circular or polygonal, when a metal layer is formed and partially removed by selective etching using photolithography or the like, it is preferable from the viewpoint of, for example, preventing variations in display quality that there are only few etching residues and that the respective areas of aperture(s) within each unit area are made as identical as possible.

As for the semitransparent second electrode 22, the material is not limited to those metal materials noted above, but any electrically conductive material that has a small work function and an adequate level of optical transmittance even without forming a particularly thin film can be employed.

According to the present embodiment, over the second electrode 22 which has such a feature of being semitransparent, the antireflective layer 46 is formed as described above so that light transmitted through the second electrode 22 is absorbed on this antireflective layer 46 and thus reflection is avoided. With either a chromium oxide or molybdenum, which is applicable as the material of the antireflective layer 46, a multilayered structure can be easily formed through a continuous evaporation process in which, after the second electrode 22 is formed by vacuum evaporation, an evaporation source is replaced with an antireflective material. In this process, when molybdenum is used as the material of the antireflective layer 46, the reflectivity of the antireflective layer 46 can be reduced to about 20% or lower, and, when a chromium oxide is used, the reflectivity can be reduced to about 5% or lower.

As for the degree of reflectivity of a material to be selected for the antireflective layer 46, it is preferable that the degree of reflectivity be determined in consideration of a required brightness as well as an emission luminance and emission efficiency of a light emitting molecule contained in the light emitting element layer 30, as well as the optical transmittance of the second electrode 22. However, in order to improve the contrast, the optical reflectivity of the antireflective layer 46 is preferably less than 50%, and more preferably 30% or less. Because light transmitted through the second electrode 22 and reaching the antireflective layer 46 includes light emitted from the light emitting element layer 30, when a material with a relatively low emission luminance is used, or when a brightness required for the element is high, more effective utilization of emitted light is desired. Therefore, in order to enable a certain amount of light (emitted light) to be reflected and emitted to outside the element, it is preferable that, for example, molybdenum that provides a reflectivity of about 20% be selected as the material of the antireflective layer 46. On the other hand, when a light emitting material with an adequate level of emission luminance achieved is used, or when the highest priority is placed on ensuring good contrast, for example, for use under circumstances of very strong ambient light, it is preferable that a chromium oxide with an extremely low reflectivity be used as the material of the antireflective layer 46.

In this case, although the material of the antireflective layer 46 is not necessarily limited to such metal-element-containing materials as described above, as the antireflective layer 46 made of molybdenum, a chromium oxide, or the like is provided on the back side of the semitransparent second electrode 22, not only the function of preventing reflection of ambient light but also a heat radiating function can be realized. Specifically, because a molybdenum layer and a chromium oxide layer have a relatively high thermal conductivity, when light is emitted in response to current drive, heat generated from the light emitting element layer 30 can be radiated to outside the element through the second electrode 22 with a high thermal conductivity and then through the antireflective layer 46. Because heat has a significant effect on the deterioration of the light emitting element layer 30 containing an organic compound, the extent to which heat radiation characteristics of the element are maintained, or improved as in the present embodiment, directly relates to the effectiveness in terms of operating lifespan and quality improvement of the element.

When a polarization layer is disposed on the viewing side of the element, such as between the first electrode and the glass substrate, or on a surface of the glass substrate as in the above-described Japanese Patent Laid-Open Publication No. Hei 7-142170, unnecessary reflection of ambient light can be avoided. However, such a polarization layer is formed by an arrangement of iodine or the like along a molecular chain in a PVA (poly-vinyl alcohol)-based film and has low heat radiation characteristics. Moreover, because the polarization layer absorbs not only ambient light incident into the element but also a large portion of emitted light from the element, the temperature of a region around the polarization layer tends to rise, and the rise in temperature has an effect on deterioration of the light emitting element. Thus, the polarization layer provided on the viewing side of the element has adverse effects in terms of improving heat radiation characteristics of the element. In contrast, according to the present embodiment, the electrode 22 on the back side of the element is designed to be semitransparent and the antireflective layer 46 with a heat radiating function is provided on a further outer side of the back-side electrode 22 so that an organic EL element with a high brightness, high contrast, a long life span, and high reliability can be achieved, which also allows promotion of heat radiation from the element while avoiding reflection of ambient light.

The above-described structure of the organic EL element provided with the antireflective layer as an example of the light emitting element according to the present embodiment can be applied to a flat panel light emitting display or the like in which such an element is incorporated in an individual display pixel. Although, as a flat panel display, an active matrix display wherein a switching element for driving each display element is provided for each pixel and a passive matrix display with a simple structure wherein no such switching element is provided are known, the organic EL element of the present embodiment can be applied to either type of display.

When applied to a passive matrix display, the element is formed so that first electrodes 20 which are transparent (but may also be semitransparent) and are formed on the transparent substrate 10, and second electrodes 22 which are semitransparent and formed on a light emitting element layer 30 which is interposed between these electrodes, as shown in the above-described FIG. 1, are arranged to separately form a stripe pattern and to intersect each other nearly at right angles, and holes and electrons are injected into the interposed light emitting element layer 30 respectively from the first electrode 20 and the second electrode 22 so that light is emitted. The antireflective layer 46 is formed on the second electrode 22.

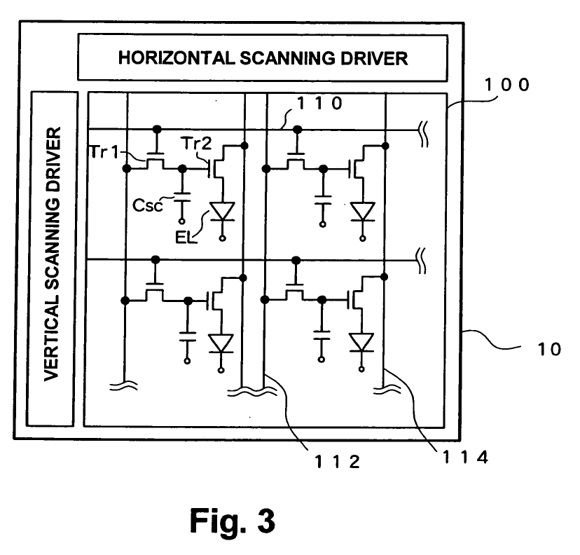

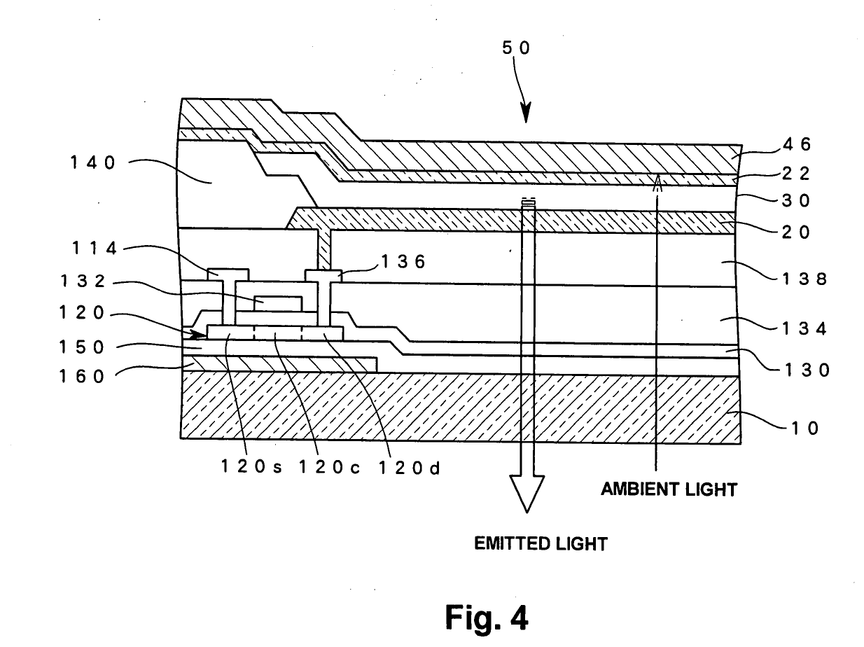

On the other hand, when the element is applied to an active matrix display, a structure can be adopted in which a thin-film transistor is formed for each pixel on the transparent substrate 10, an insulating layer is formed covering the thin-film transistor, the transparent first electrode 20 connected to the thin-film transistor and formed in an individual pattern for each pixel, the light emitting element layer 30, and the semitransparent second electrode 22 which is common to all pixels are successively layered on the insulating layer, and, in addition, the antireflective layer 46 is formed on the common second electrode 22. FIG. 3 shows a schematic circuit layout of such an active-matrix organic EL display, and FIG. 4 shows a partial cross-sectional structure of one pixel in such an organic EL display.

First, a display section 100 including multiple pixels arranged in a matrix is formed on the transparent substrate 10, and, for each pixel, individually, the organic EL element (EL) 50, a switching element (in this example, a thin-film transistor, or “TFT”) for controlling light emission from the organic EL element 50 in each pixel, and a storage capacitor Csc for storing display data are provided.

According to the example shown in FIG. 3, first and second thin-film transistors Tr1 and Tr2 are formed in each pixel, the first transistor Tr1 is connected to a scanning line 110, and when a scanning signal is applied and the first transistor Tr1 is controlled to turn on, a voltage signal based on content to be displayed applied to a corresponding data line 112 is applied via the first thin-film transistor Tr1 to a gate of the second thin-film transistor Tr2, and the storage capacitor Csc connected between the two thin-film transistors Tr1 and Tr2 stores the voltage signal for a fixed period of time. The second thin-film transistor Tr2 supplies a current based on the voltage stored at the storage capacitor Csc and applied to the gate, from a power supply line 114 to the anode (hole injection electrode) 20 of the organic EL element connected to the second thin-film transistor Tr2. The organic EL element 50 emits light of a luminance corresponding to the amount of the supplied current, and, although a certain amount of light is lost at the antireflective layer 46 on the back side of the second electrode 22, most of the emitted light passes through the transparent first electrode 20 and the transparent substrate 10, and is emitted from the device.

A schematic cross-sectional structure shown in FIG. 4 illustrates the second thin-film transistor Tr2 and the organic EL element 50 connected to the second thin-film transistor Tr2 in one pixel of the active-matrix organic EL display as shown in FIG. 3. While not shown in the example of FIG. 4, the first thin-film transistor Tr1 has a structure similar to that of the thin-film transistor Tr2. An active layer 120 of each of the thin-film transistors Tr1 and Tr2 is formed using polycrystalline silicon in which amorphous silicon is polycrystallized by laser annealing. Further, in the present embodiment, these thin-film transistors Tr1 and Tr2 are of “top-gate-type” TFTs which comprises a gate electrode 132 above a gate insulating layer 130 formed covering the active layer 120. In the active layer 120, a channel region 120c is formed in a region positioned below the gate electrode 132, and a source region 120s and a drain region 120d doped with impurities of respective predetermined conductivity types are formed respectively on both sides of the channel region 120c.

An interlayer insulating layer 134 is formed covering the gate electrode 132 and most of the surface of the substrate, while the power supply line 114 is connected to one of the source region 120s and the drain region 120d and a contact electrode 136 is connected to the other region via respective contact holes opened through the interlayer insulating layer 134 and the gate insulating layer 130. A first planarization insulating layer 138 (which may be a typical interlayer insulating film) made of either an inorganic material or an organic material is further formed so as to cover all of these elements, the first electrode 20 of the organic EL element 50 is layered on the planarization insulating layer 138, and a second planarization insulating layer 140 is layered so as to cover an end portion of the first electrode 20. The first electrode 20 is connected to the contact electrode 136 through a contact hole formed in the first planarization insulating layer 138. Over the first electrode 20, as described, the light emitting element layer 30, the second electrode 22, and the antireflective layer 46 are formed, in that order.

In the structure as described above, because the display emits light from the transparent substrate 10 side, in the top-gate-type first and second thin-film transistors Tr1 and Tr2, the active layer 120 made of polycrystalline silicon in which leakage is likely to occur when light is applied is positioned on the light emitting side. For this reason, in order to avoid occurrence of leakage current caused by application of ambient light, as shown in FIG. 4, it is preferable that, for example, a light-blocking layer 160 be formed at least between the active layer 120 and the substrate 10 of the first and second thin-film transistors Tr1 and Tr2 while an insulating layer 150 having a multilayer structure wherein SiO₂ and SiNx are layered from the active layer side is interposed between the active layer 120 and the light-blocking layer 160. In the example structure shown in FIG. 4, because the light-blocking layer 160 is formed in a position closest to the light emitting side and is typically formed of a metal material, if the surface has a high reflectivity, as described above, there are possibilities of contrast reduction and other adverse effects exerted on display quality and the like. Therefore, it is still more preferable that a light-blocking material with a low surface reflectivity, such as a chromium oxide or molybdenum, is used to form the light-blocking layer 160, as in the case of the back-side antireflective layer 46.

As described above, an antireflective light-blocking layer with a low optical reflectivity is formed as the light-blocking layer 160, which is formed in a region where the thin-film transistors Tr1 and Tr2 are formed and that is on the light emitting side. Further, the second electrode 22 formed on the back side is designed to be semitransparent so that the reflectivity is reduced, and, in addition, the antireflective layer 46 with a low reflectivity is provided on the back side of the second electrode 22, thereby enabling very high contrast display and achieving an organic EL display with both high brightness and high reliability.

What is claimed is:

1. A light emitting element, comprising a light emitting element layer between a first electrode and a second electrode, wherein
one of the first electrode and the second electrode is disposed as a light-emitting-side electrode on a side from which light is emitted to outside,
another one of the first electrode and the second electrode, which is formed as a back-side electrode positioned on a back side of the light-emitting-side electrode, is formed as a semitransparent electrode for partially transmitting incident light from a side of the light emitting element layer, and
an antireflective layer is provided on a back side of the semitransparent electrode.

2. A light emitting element according to claim 1, wherein a metal layer with a thickness reduced to a level of a thin film through which light can be transmitted or a metal layer with a mesh pattern provided with apertures for transmitting light is used in the semitransparent electrode.

3. A light emitting element according to claim 1, wherein an Ag layer or an MgAg layer with a thickness of 20 nm or less is used in the semitransparent electrode.

4. A light emitting element according to claim 1, wherein molybdenum or a chromium oxide is used in the antireflective layer.

5. A light emitting display, comprising a light emitting element with a light emitting element layer provided between a first electrode and a second electrode, wherein
the first electrode is formed over a transparent substrate disposed on a side from which light is emitted to outside of the display and is an electrode capable of transmitting light emitted from the light emitting element layer,
the second electrode is formed on a back side of the first electrode so as to be opposed to the first electrode with the light emitting element layer interposed therebetween and is a semitransparent electrode for partially transmitting incident light from a side of the light emitting element layer, and
an antireflective layer is provided on a back side of the second electrode.

6. A light emitting display according to claim 5, wherein a metal layer with a thickness reduced to a level of a thin film through which light can be transmitted or a metal layer with a mesh pattern provided with apertures for transmitting light is used in the semitransparent electrode.

7. A light emitting display according to claim 5, wherein an Ag layer or an MgAg layer with a thickness of 20 nm or less is used in the semitransparent electrode.

8. A light emitting display according to claim 5, wherein molybdenum or a chromium oxide is used in the antireflective layer.

9. A light emitting display according to claim 5, the display further comprising a plurality of pixels, each pixel comprising the light emitting element and a thin-film transistor for controlling light emission frothier light emitting element, wherein
the thin-film transistor is formed closer to the substrate than the light emitting element, and
an antireflective light-blocking layer for blocking entry of ambient light and for preventing reflection of ambient light is provided between at least a region where an active layer of the thin-film transistor is formed and the substrate.

10. A display, comprising an electroluminescence element with a light emitting element layer provided between an anode and a cathode, wherein
the anode is formed over a transparent substrate disposed on a side from which light is emitted to outside and comprises an electrode capable of transmitting light emitted from the light emitting element layer,
the cathode is formed on a back side of the anode so as to be opposed to the anode with the light emitting element layer interposed therebetween and comprises a semitransparent electrode capable of partially transmitting incident light from a side of the light emitting element layer, and
an antireflective layer is formed on a back side of the cathode.

11. A display according to claim 10, wherein a metal layer with a thickness reduced to a level of a thin film through which light can be transmitted or a metal layer with a mesh pattern provided with apertures for transmitting light is used in the semitransparent electrode.

12. A display according to claim 10, wherein an Ag layer or an MgAg layer with a thickness of 20 nm or less is used in the semitransparent electrode.

13. A display according to claim 10, wherein molybdenum or a chromium oxide is used in the antireflective layer.

14. A display according to claim 10, the display further comprising a plurality of pixels, each pixel comprising the electroluminescence element and a thin-film transistor for controlling light emission from the electroluminescence element, wherein
the thin-film transistor is formed closer to the substrate than the electroluminescence element, and
an antireflective light-blocking layer for blocking entry of ambient light and for preventing reflection of ambient light is provided between at least a region where an active layer of the thin-film transistor is formed and the substrate.
